(19) United States
(12) Patent Application Publication
(10) Pub. No.: US 2009/0081855 A1
(43) Pub. Date: Mar. 26, 2009

(54) FABRICATION METHOD OF POLYSILICON LAYER

(75) Inventors: Yi-Yun Tsai, Penghu County (TW); Shao-Yu Chiu, Taichung County (TW); Chia-Hsuan Ma, Changhua County (TW); Pei-Chen Yu, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 12/053,635

(22) Filed: Mar. 24, 2008

(30) Foreign Application Priority Data
Sep. 26, 2007 (TW) 96135674

(51) Int. Cl. H01L 21/20

(52) U.S. Cl. 438/486; 257/E21.09

(57) ABSTRACT

A fabrication method of a polysilicon layer is provided. First, a substrate is provided. Then, an amorphous silicon layer is formed on the substrate. After that, a patterned photomask having a light transmitting area and a light shielding area is provided, and the amorphous silicon layer is irradiated with a light by using the patterned photomask as a mask, wherein the amorphous silicon layer corresponding to the light transmitting area is transformed into a hydrophilic amorphous silicon layer, and the amorphous silicon layer corresponding to the light shielding area remains as a hydrophobic amorphous silicon layer. Next, a hydrophilic metal catalyst is provided and disposed on the hydrophilic amorphous silicon layer. After that, an annealing process is performed to transform the hydrophilic metal catalyst into a metal catalyst layer, and the metal catalyst layer reacts with the amorphous silicon layer to form a polysilicon layer.

### CROSS-REFERENCE TO RELATED APPLICATION

This application claims the priority benefit of Taiwan application serial no. 96135674, filed on Sep. 26, 2007. The entirety the above-mentioned patent application is hereby incorporated by reference herein and made a part of specification.

### BACKGROUND OF THE INVENTION

1. Field of the Invention

The present invention generally relates to a fabrication method of a semiconductor layer, in particular, to a fabrication method of a polysilicon layer.

2. Description of Related Art

Thin film transistor liquid crystal display (TFT-LCD) has become the mainstream in today's flat panel display market. TFT-LCD can be categorized into amorphous silicon TFT-LCD and low-temperature polysilicon (LTPS) TFT-LCD according to the material of the channel layer thereof.

The electron mobility of an LTPS TFT is above 200 cm²/V-sec so that the LTPS TFT can be fabricated in small size. Thus, high aperture ratio can be achieved by an LTPS TFT-LCD, and accordingly the brightness of the LTPS TFT-LCD can be increased while the power consumption thereof can be reduced. Moreover, due to the increment in the electron mobility, part of the driving circuit can be fabricated on a glass substrate so that the fabrication cost of the display panel can be greatly reduced. Thereby, the research and development of flat panel display is mostly focused on the development of the LTPS TFT-LCD.

Generally speaking, the polysilicon layer serving as a channel layer in an LTPS TFT is usually fabricated through two different methods.

The first method is to fabricate a polysilicon layer through an excimer laser annealing (ELA) process. According to this method, an amorphous silicon layer on a substrate is melted by applying a laser beam on the amorphous silicon layer. After that, the melted silicon is cooled down and is crystallized so that the amorphous silicon layer is transformed into a polysilicon layer. However, this method comes along with many problems, such as high power consumption, small grain size, much defects in the polysilicon layer, poor uniformity, and narrow process window etc.

The second method is to fabricate a polysilicon layer through an annealing process and a metal induced crystallization (MIC) or a metal induced lateral crystallization (MILC) process. This fabrication method is developed for overcoming the problems in foregoing ELA method. According to this method, a metal is applied and reacted with silicon at a low temperature so as to form a metal silicide, and this metal silicide induces the crystallization of an amorphous silicon layer so that the amorphous silicon layer is transformed into a polysilicon layer.

FIGS. 1A˜1E are cross-sectional views illustrating a conventional fabrication method of a polysilicon layer. First, referring to FIG. 1A, an adhesive layer 110, a barrier layer 120, and an amorphous silicon layer 130 are formed on a substrate 100. Then, referring to FIG. 1B, a metal catalyst layer 140 is formed on the amorphous silicon layer 130.

Next, referring to FIG. 1C, the metal catalyst layer 140 is patterned through a photolithography and etching process so as to form a patterned metal catalyst layer 140′. After that, referring to FIG. 1D, an annealing process 150 is performed to transform the amorphous silicon layer 130 into a polysilicon layer 160, wherein the amorphous silicon layer 130 in contact with the patterned metal catalyst layer 140′ is transformed into a polysilicon layer 162 through metal induced crystallization (MIC), and the amorphous silicon layer 130 not in contact with the patterned metal catalyst layer 140′ is transformed into a polysilicon layer 164 through metal induced lateral crystallization (MILC). Then referring to FIG. 1E, the patterned metal catalyst layer 140′ is removed, and by now the fabrication of the polysilicon layer 160 is completed.

FIGS. 2A˜2F are cross-sectional views illustrating another conventional fabrication method of a polysilicon layer. First, referring to FIG. 2A, an adhesive layer 210, a barrier layer 220, and an amorphous silicon layer 230 are formed on a substrate 200. Then referring to FIG. 2B, a silicon oxide layer 240 is formed on the amorphous silicon layer 230.

Thereafter, referring to FIG. 2C, the silicon oxide layer 240 is patterned through a photolithography and etching process so as to form a patterned silicon oxide layer 240′. Next, referring to FIG. 2D, a metal catalyst layer 250 is formed on the substrate 200. After that, referring to FIG. 2E, an annealing process 260 is performed to transform the amorphous silicon layer 230 into a polysilicon layer 270, wherein the amorphous silicon layer 230 in contact with the metal catalyst layer 250 is transformed into a polysilicon layer 272 through MIC, and the amorphous silicon layer 230 not in contact with the metal catalyst layer 250 is transformed into a polysilicon layer 274 through MILC. Then referring to FIG. 2F, the metal catalyst layer 250 and the patterned silicon oxide layer 240′ are removed, and by now the fabrication of the polysilicon layer 270 is completed.

However, in both of foregoing two methods, a photolithography and etching process has to be performed in order to define a patterned metal catalyst layer 140′ (as shown in FIG. 1C) or a patterned silicon oxide layer 240′ (as shown in FIG. 2C). Accordingly, a photoresist and a photomask have to be used in the photolithography process and an etching liquid or an etching gas has to be used in the etching process. Thereby, the conventional fabrication methods of polysilicon layer cannot be simplified and the fabrication cost thereof is high.

### SUMMARY OF THE INVENTION

Accordingly, the present invention is directed to a fabrication method of a polysilicon layer, wherein the polysilicon layer is fabricated through surface treatment, self-assembled monolayer (SAM), and metal induced crystallization (MIC) so as to simplify the fabrication process and to reduce the fabrication cost of the polysilicon layer.

The present invention provides a fabrication method of a polysilicon layer. The fabrication method includes following steps. First, a substrate is provided. Then, an amorphous silicon layer is formed on the substrate. Next, a patterned photomask having a light transmitting area and a light shielding area is provided, and the amorphous silicon layer is irradiated with a light by using the patterned photomask as a mask, wherein the amorphous silicon layer corresponding to the light transmitting area is transformed into a hydrophilic amorphous silicon layer, and the amorphous silicon layer corresponding to the light shielding area remains as a hydrophobic amorphous silicon layer. After that, a hydrophilic metal catalyst is provided and disposed on the hydrophilic amorphous silicon layer. Next, an annealing process is performed to make the hydrophilic metal catalyst to form a metal catalyst layer, and the metal catalyst layer reacts with the amorphous silicon layer to form the polysilicon layer.

According to an embodiment of the present invention, the wavelength of the light is between 400 nm and 800 nm.

According to an embodiment of the present invention, the hydrophilic metal catalyst is provided through inkjet printing or transfer printing.

According to an embodiment of the present invention, the hydrophilic metal catalyst includes metal nanoparticles.

According to an embodiment of the present invention, the material of the hydrophilic metal catalyst is nickel, copper, silver, gold, or a combination of foregoing metals.

According to an embodiment of the present invention, the amorphous silicon layer in contact with the metal catalyst layer is transformed into the polysilicon layer through MIC, and the amorphous silicon layer not in contact with the metal catalyst layer is transformed into the polysilicon layer through metal induced lateral crystallization (MILC).

According to an embodiment of the present invention, the fabrication method further includes forming an adhesive layer and a barrier layer on the substrate before forming the amorphous silicon layer on the substrate, wherein the adhesive layer is disposed on the substrate, and the barrier layer is disposed on the adhesive layer. The adhesive layer and the barrier layer may be formed through chemical vapor deposition (CVD). The material of the adhesive layer may be silicon nitride. The material of the barrier layer may be silicon oxide.

According to an embodiment of the present invention, the fabrication method further includes removing the metal catalyst layer after transforming the amorphous silicon layer into the polysilicon layer.

The present invention further provides a fabrication method of a polysilicon layer. The fabrication method includes following steps. First, a substrate is provided. Then, an amorphous silicon layer is formed on the substrate. After that, a patterned hydrophilic material layer is formed on the amorphous silicon layer. Next, a hydrophilic metal catalyst is provided and disposed on the patterned hydrophilic material layer. Next, an annealing process is performed to make the hydrophilic metal catalyst to form a metal catalyst layer, and the metal catalyst layer reacts with the amorphous silicon layer to form the polysilicon layer.

According to an embodiment of the present invention, the patterned hydrophilic material layer is provided through inkjet printing or transfer printing.

According to an embodiment of the present invention, the hydrophilic metal catalyst is provided through inkjet printing.

According to an embodiment of the present invention, the hydrophilic metal catalyst includes metal nanoparticles.

According to an embodiment of the present invention, the material of the hydrophilic metal catalyst is nickel, copper, silver, gold, or a combination of foregoing metals.

According to an embodiment of the present invention, the amorphous silicon layer in contact with the metal catalyst layer is transformed into the polysilicon layer through MIC, and the amorphous silicon layer not in contact with the metal catalyst layer is transformed into the polysilicon layer through MILC.

According to an embodiment of the present invention, the fabrication method further includes forming an adhesive layer and a barrier layer on the substrate before forming the amorphous silicon layer on the substrate, wherein the adhesive layer is disposed on the substrate, and the barrier layer is disposed on the adhesive layer. The adhesive layer and the barrier layer may be formed through CVD. The material of the adhesive layer may be silicon nitride. The material of the barrier layer may be silicon oxide.

According to an embodiment of the present invention, the fabrication method further includes removing the patterned hydrophilic material layer and the metal catalyst layer after transforming the amorphous silicon layer into the polysilicon layer.

According to the present invention, a polysilicon layer is fabricated through surface treatment, SAM, MIC and MILC, and the photolithography and etching process in the conventional technique which comprises many steps and requires many chemical reagents is omitted. Thereby, the polysilicon layer fabrication method provided by the present invention can simplify the fabrication process and reduce the fabrication cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1E are cross-sectional views illustrating a conventional fabrication method of a polysilicon layer.

FIGS. 2A˜2F are cross-sectional views illustrating another conventional fabrication method of a polysilicon layer.

FIGS. 3A˜3E are cross-sectional views illustrating a fabrication method of a polysilicon layer according to an embodiment of the present invention.

FIGS. 4A˜4E are cross-sectional views illustrating a fabrication method of a polysilicon layer according to another embodiment of the present invention.

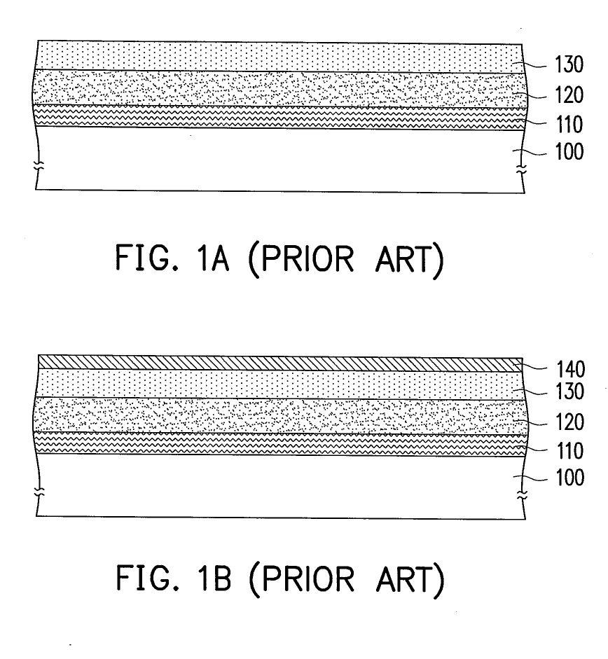

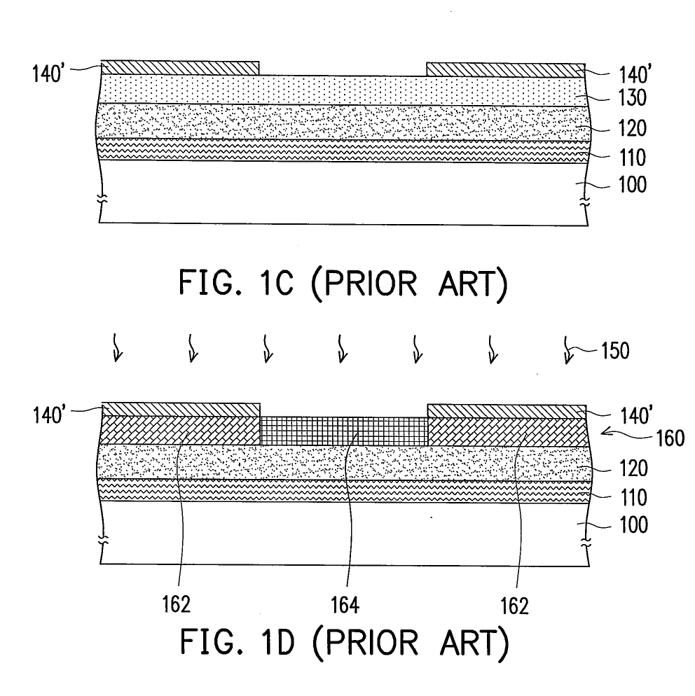

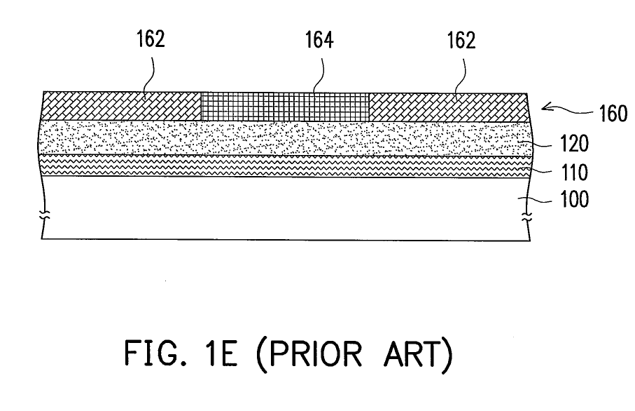

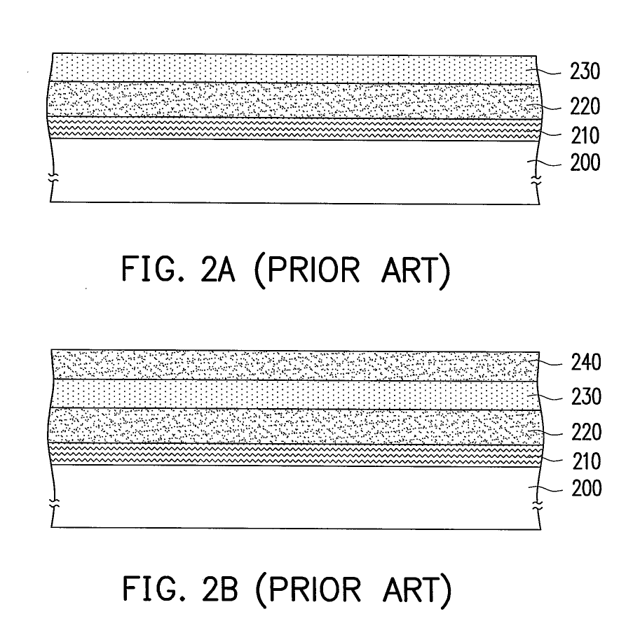

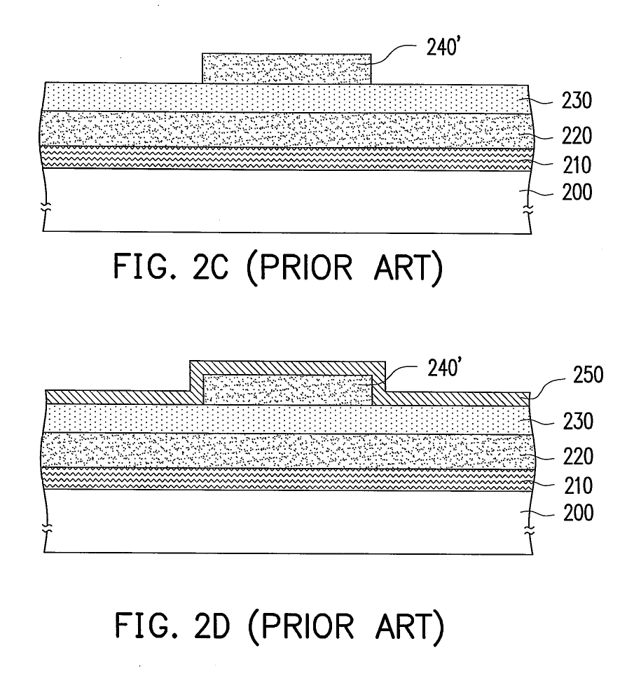

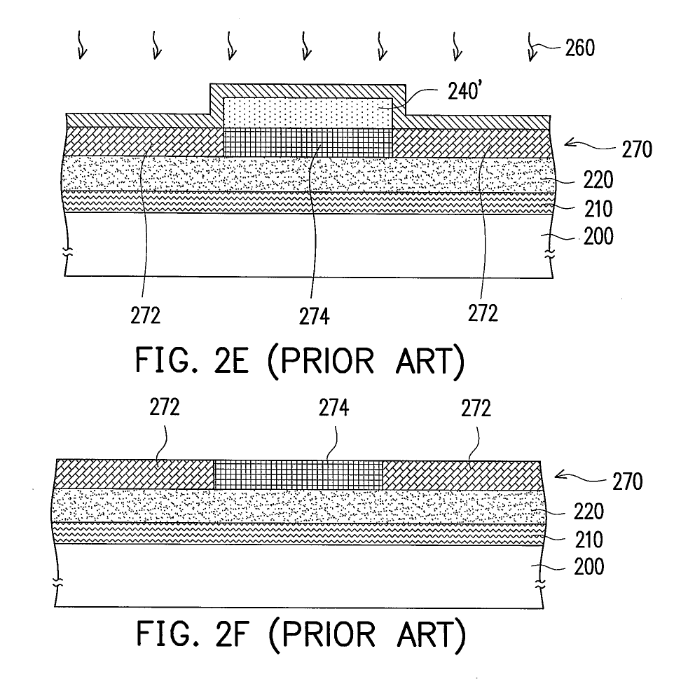

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

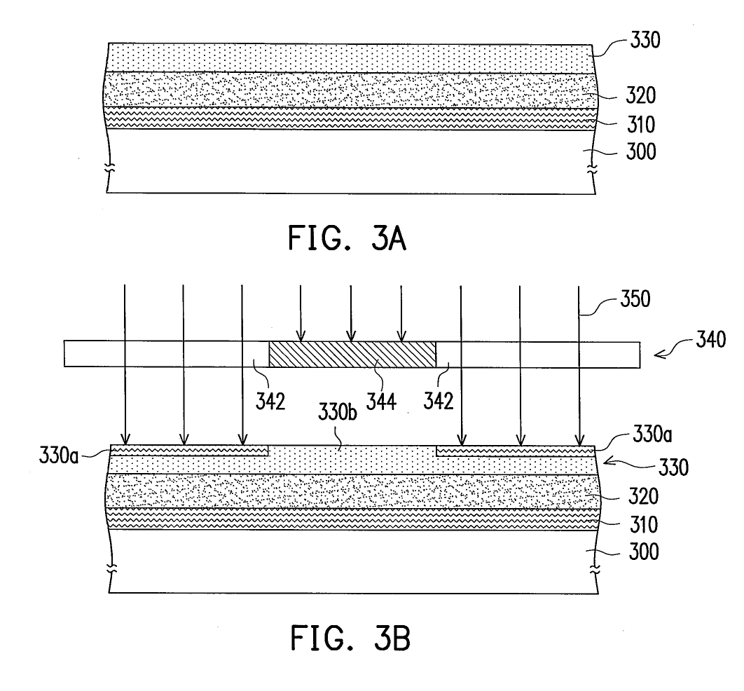

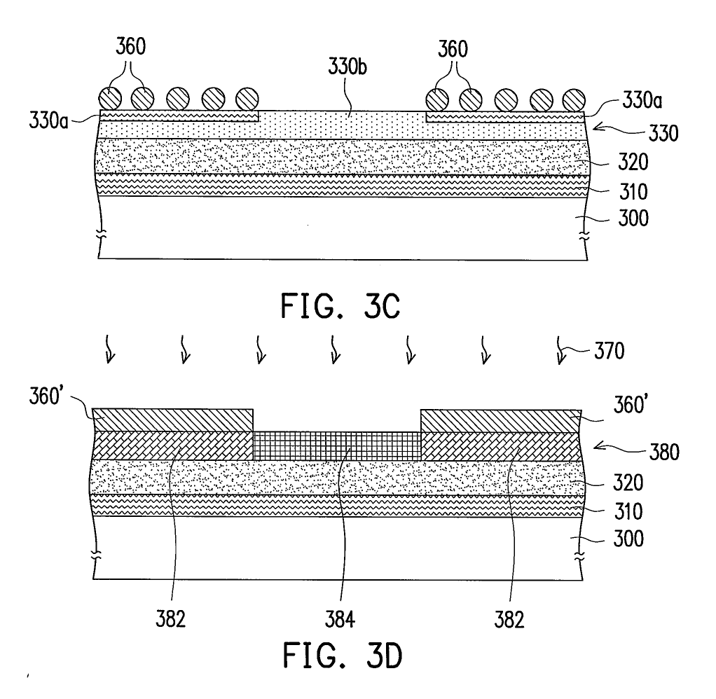

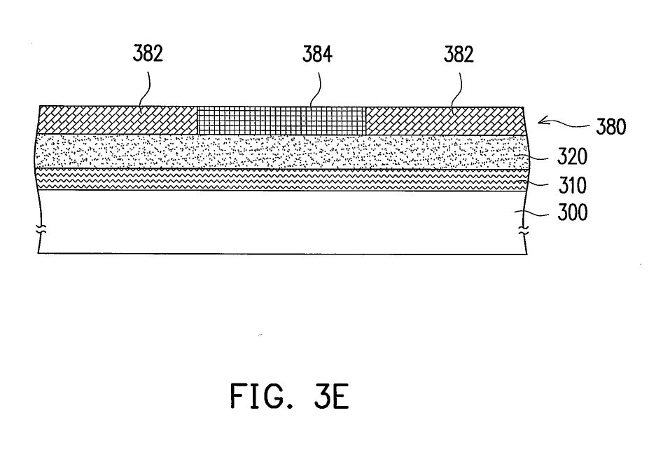

FIGS. 3A˜3E are cross-sectional views illustrating a fabrication method of a polysilicon layer according to the first embodiment of the present invention. First, referring to FIG. 3A, a substrate 300 is provided, wherein the substrate 300 may be a glass substrate or a silicon substrate.

Next, referring to FIG. 3A again, an amorphous silicon layer 330 is formed on the substrate 300. The amorphous silicon layer 330 may be formed through chemical vapour deposition (CVD). In an embodiment of the present invention, an adhesive layer 310 and a barrier layer 320 are further formed on the substrate 300 before the amorphous silicon layer 330 is formed on the substrate 300, wherein the adhesive layer 310 is disposed on the substrate 300, and the barrier layer 320 is disposed on the adhesive layer 310. The adhesive layer 310 and the barrier layer 320 may be formed through CVD. The material of the adhesive layer 310 may be silicon nitride, and the material of the barrier layer 320 may be silicon oxide.

The adhesive layer 310 allows the barrier layer 320 and the amorphous silicon layer 330 to adhere to the substrate 300. Besides, the barrier layer 320 prevents impurities from the substrate 300 from contaminating the amorphous silicon layer 330. In particular, the barrier layer 320 stores heat so that in the subsequent annealing process 370, the amorphous silicon layer 330 can be kept at a temperature at which the amorphous silicon layer 330 can be transformed into the polysilicon layer 380. However, the amorphous silicon layer 330 may also be directly formed on the substrate 300.

Thereafter, referring to FIG. 3B, a patterned photomask 340 having a light transmitting area 342 and a light shielding area 344 is provided, and the amorphous silicon layer 330 is irradiated with a light 350 by using the patterned photomask 340 as a mask, wherein the amorphous silicon layer 330 corresponding to the light transmitting area 342 is transformed into a hydrophilic amorphous silicon layer 330a, and the amorphous silicon layer 330 corresponding to the light shielding area 344 remains as a hydrophobic amorphous silicon layer 330b. The wavelength of the light 350 may be between 400 nm and 800 nm. In short, the surface of the amorphous silicon layer 330 is treated through light irradiation so as to transform a part of the amorphous silicon layer 330 into the hydrophilic amorphous silicon layer 330a and allow another part of the amorphous silicon layer 330 to remain as the hydrophobic amorphous silicon layer 330b.

After that, referring to FIG. 3C, a hydrophilic metal catalyst 360 is provided and disposed on the hydrophilic amorphous silicon layer 330a. The hydrophilic metal catalyst 360 may be provided through inkjet printing or transfer printing. The hydrophilic metal catalyst 360 may be metal nanoparticles, and the material of the hydrophilic metal catalyst 360 may be nickel, copper, silver, gold, or a combination of foregoing metals. To be specific, the hydrophilic metal catalyst 360 can be formed on the hydrophilic amorphous silicon layer 330a through self-assembled monolayer (SAM) process because there is very strong action between the hydrophilic metal catalyst 360 and the hydrophilic amorphous silicon layer 330a.

Next, referring to FIG. 3D, an annealing processing 370 is performed to make the hydrophilic metal catalyst 360 to form a metal catalyst layer 360′, and the metal catalyst layer 360′ reacts with the amorphous silicon layer 330 to form a polysilicon layer 380. The temperature of the annealing process 370 may be between 450° C. and 750° C. Here the heat stored by the barrier layer 320 can be emitted to allow the amorphous silicon layer 330 to remain at a temperature at which the amorphous silicon layer 330 can be transformed into the polysilicon layer 380. Particularly, the amorphous silicon layer 330 in contact with the metal catalyst layer 360′ is transformed into a polysilicon layer 382 through metal induced crystallization (MIC), and the amorphous silicon layer 330 not in contact with the metal catalyst layer 360′ is transformed into a polysilicon layer 384 through metal induced lateral crystallization (MILC). By now, the fabrication of the polysilicon layer 380 is completed.

Moreover, the metal catalyst layer 360′ may be removed after the amorphous silicon layer 330 is transformed into the polysilicon layer 380, as shown in FIG. 3E. After that, the polysilicon layer 380 may be further used, for example, as a channel layer of a thin film transistor (not shown), and other components, such as the gate and a passivation layer of the thin film transistor may be further fabricated.

As described above, the photolithography and etching process in the conventional technique is not performed in the fabrication method of a polysilicon layer as illustrated in FIGS. 3A˜3E, and accordingly the fabrication process is simplified and the fabrication cost is reduced.

### Second Embodiment

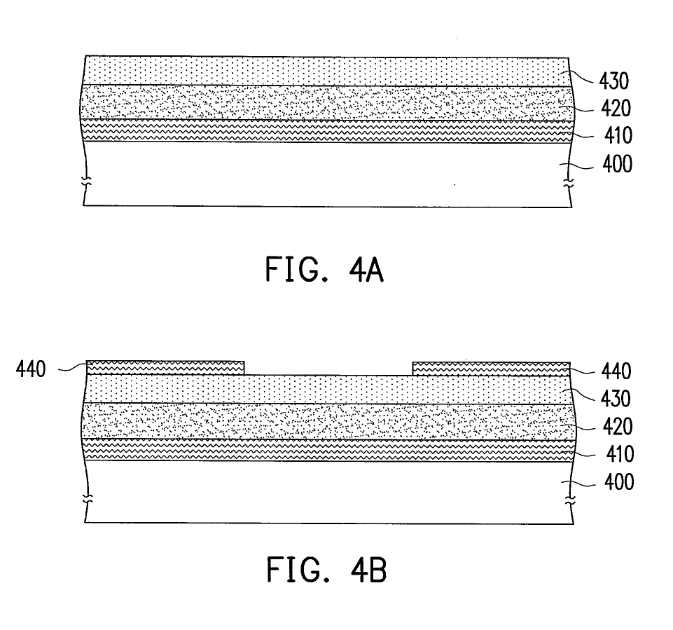

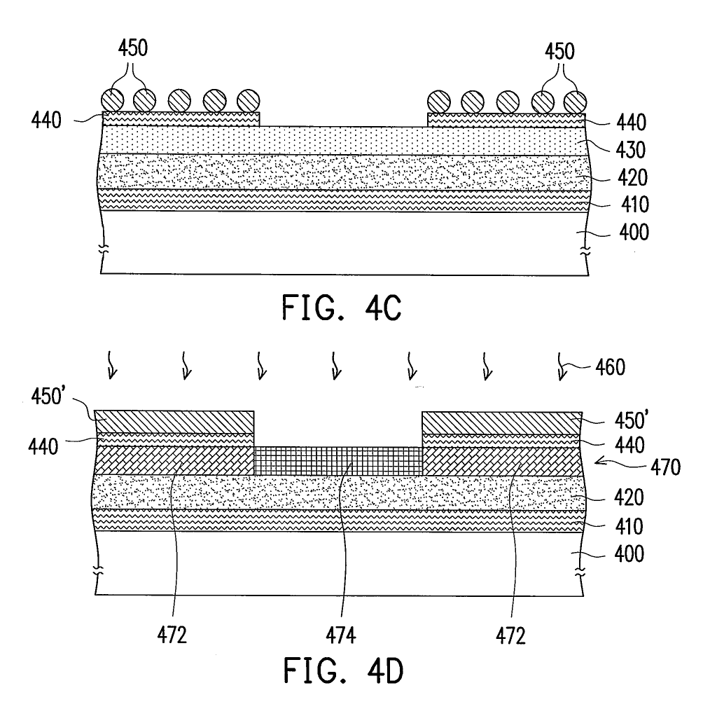

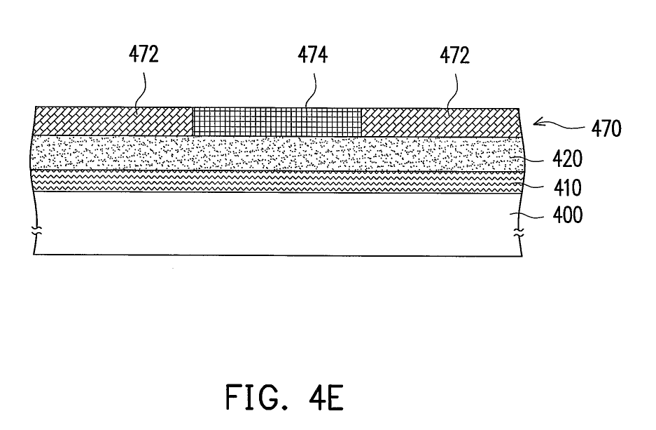

FIGS. 4A˜4E are cross-sectional views illustrating a fabrication method of a polysilicon layer according to the second embodiment of the present invention. First, referring to FIG. 4A, a substrate 400 is provided, wherein the substrate 400 may be a glass substrate or a silicon substrate.

Next, referring to FIG. 4A again, an amorphous silicon layer 430 is formed on the substrate 400. The amorphous silicon layer 430 may be formed through CVD. In an embodiment of the present invention, an adhesive layer 410 and a barrier layer 420 are further formed on the substrate 400 before the amorphous silicon layer 430 is formed on the substrate 400, wherein the adhesive layer 410 is disposed on the substrate 400, and the barrier layer 420 is disposed on the adhesive layer 410. The adhesive layer 410 and the barrier layer 420 may be formed through CVD. The material of the adhesive layer 410 may be silicon nitride, and the material of the barrier layer 420 may be silicon oxide. The functions of the adhesive layer 410 and the barrier layer 420 have been explained in the first embodiment therefore will not be described herein.

Next, referring to FIG. 4B, a patterned hydrophilic material layer 440 is formed on the amorphous silicon layer 430. The patterned hydrophilic material layer 440 may be provided through inkjet printing or transfer printing. In other words, the surface of the amorphous silicon layer 430 is treated so as to form a hydrophilic area and a hydrophobic area on the surface of the amorphous silicon layer 430. The material of the patterned hydrophilic material layer 440 may be a hydrophilic functional group which contains one of a NH₂ functional group, a SH functional group, a COH functional group, or a COOH functional group.

After that, referring to FIG. 4C, a hydrophilic metal catalyst 450 is provided and disposed on the patterned hydrophilic material layer 440. The hydrophilic metal catalyst 450 may be provided through inkjet printing. The hydrophilic metal catalyst 450 may be metal nanoparticles, and the material of the hydrophilic metal catalyst 450 is nickel, copper, silver, or gold. To be specific, the hydrophilic metal catalyst 450 may be formed on the patterned hydrophilic material layer 440 through SAM process because there is very strong action between the hydrophilic metal catalyst 450 and the patterned hydrophilic material layer 440.

Thereafter, referring to FIG. 4D, an annealing process 460 is performed to make the hydrophilic metal catalyst 450 to form a metal catalyst layer 450′, and the metal catalyst layer 450′ reacts with the amorphous silicon layer 430 to form a polysilicon layer 470. The temperature of the annealing process 460 may be between 450° C. and 750° C. In particular, the amorphous silicon layer 430 in contact with the metal catalyst layer 450′ is transformed into a polysilicon layer 472 through MIC, and the amorphous silicon layer 430 not in contact with the metal catalyst layer 450′ is transformed into a polysilicon layer 474 through MILC. By now, the fabrication of the polysilicon layer 470 is completed.

Moreover, the patterned hydrophilic material layer 440 and the metal catalyst layer 450′ may be further removed after the amorphous silicon layer 430 is transformed into the polysilicon layer 470, as shown in FIG. 4E.

As described above, the photolithography and etching process in the conventional technique is not performed in the fabrication method of a polysilicon layer as illustrated in FIGS. 4A˜4E, and accordingly the fabrication process is simplified and the fabrication cost is reduced.

In summary, the fabrication method of a polysilicon layer provided by the present invention has at least following advantages.

The surface of an amorphous silicon layer is treated through a surface treatment technique and a metal catalyst layer is reacted with the treated surface of the amorphous silicon layer so as to form the polysilicon layer. As described above, the etching process in the conventional technique is omitted and accordingly no etching liquid or etching gas is required, thus, the fabrication process is simplified and the fabrication cost is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method of a polysilicon layer, comprising:
providing a substrate;
forming an amorphous silicon layer on the substrate;
providing a patterned photomask having a light transmitting area and a light shielding area, and irradiating a light on the amorphous silicon layer by using the patterned photomask as a mask, wherein the amorphous silicon layer corresponding to the light transmitting area is transformed into a hydrophilic amorphous silicon layer, and the amorphous silicon layer corresponding to the light shielding area remains as a hydrophobic amorphous silicon layer;
providing a hydrophilic metal catalyst, and disposing the hydrophilic metal catalyst on the hydrophilic amorphous silicon layer; and
performing an annealing process to make the hydrophilic metal catalyst to form a metal catalyst layer, the metal catalyst layer reacting with the amorphous silicon layer to form the polysilicon layer.

2. The fabrication method according to claim 1, wherein the wavelength of the light is between 400 nm and 800 nm.

3. The fabrication method according to claim 1, wherein the hydrophilic metal catalyst is provided through inkjet printing or transfer printing.

4. The fabrication method according to claim 1, wherein the hydrophilic metal catalyst comprises metal nanoparticles.

5. The fabrication method according to claim 1, wherein the material of the hydrophilic metal catalyst comprises nickel, copper, silver, gold, or a combination thereof.

6. The fabrication method according to claim 1, wherein the amorphous silicon layer in contact with the metal catalyst layer is transformed into the polysilicon layer through metal induced crystallization (MIC), and the amorphous silicon layer not in contact with the metal catalyst layer is transformed into the polysilicon layer through metal induced lateral crystallization (MILC).

7. The fabrication method according to claim 1, further comprising forming an adhesive layer and a barrier layer on the substrate before forming the amorphous silicon layer on the substrate, wherein the adhesive layer is disposed on the substrate, and the barrier layer is disposed on the adhesive layer.

8. The fabrication method according to claim 7, wherein the formation method of the adhesive layer and the barrier layer comprises chemical vapour deposition (CVD).

9. The fabrication method according to claim 7, wherein the material of the adhesive layer comprises silicon nitride.

10. The fabrication method according to claim 7, wherein the material of the barrier layer comprises silicon oxide.

11. The fabrication method according to claim 1, further comprising removing the metal catalyst layer after transforming the amorphous silicon layer into the polysilicon layer.

12. A fabrication method of a polysilicon layer, comprising:
providing a substrate;
forming an amorphous silicon layer on the substrate;
forming a patterned hydrophilic material layer on the amorphous silicon layer;
providing a hydrophilic metal catalyst, and disposing the hydrophilic metal catalyst on the patterned hydrophilic material layer; and
performing an annealing process to make the hydrophilic metal catalyst to form a metal catalyst layer, the metal catalyst layer reacting with the amorphous silicon layer to form the polysilicon layer.

13. The fabrication method according to claim 12, wherein the patterned hydrophilic material layer is provided through transfer printing or inkjet printing.

14. The fabrication method according to claim 12, wherein the hydrophilic metal catalyst is provided through inkjet printing.

15. The fabrication method according to claim 12, wherein the hydrophilic metal catalyst comprises metal nanoparticles.

16. The fabrication method according to claim 12, wherein the material of the hydrophilic metal catalyst comprises nickel, copper, silver, gold, or a combination thereof.

17. The fabrication method according to claim 12, wherein the amorphous silicon layer in contact with the metal catalyst layer is transformed into the polysilicon layer through MIC, and the amorphous silicon layer not in contact with the metal catalyst layer is transformed into the polysilicon layer through MILC.

18. The fabrication method according to claim 12, further comprising forming an adhesive layer and a barrier layer on the substrate before forming the amorphous silicon layer on the substrate, wherein the adhesive layer is disposed on the substrate, and the barrier layer is disposed on the adhesive layer.

19. The fabrication method according to claim 18, wherein the formation method of the adhesive layer and the barrier layer comprises CVD.

20. The fabrication method according to claim 18, wherein the material of the adhesive layer comprises silicon nitride.

21. The fabrication method according to claim 18, wherein the material of the barrier layer comprises silicon oxide.

22. The fabrication method according to claim 12, further comprising removing the patterned hydrophilic material layer and the metal catalyst layer after transforming the amorphous silicon layer into the polysilicon layer.
